(19) United States
(12) Patent Application Publication
(10) Pub. No.: US 2016/0234929 A1
(43) Pub. Date: Aug. 11, 2016

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Joon-Sung LEE, Seoul (KR); Suk-Hyeon CHO, Suwon-si (KR); Yong-Sam LEE, Yongin-si (KR)

(73) Assignee: SAMSUNG ELECTRO-MECHANICS CO., LTD., Suwon-si (KR)

(21) Appl. No.: 15/019,714

(22) Filed: Feb. 9, 2016

(30) Foreign Application Priority Data
Feb. 10, 2015 (KR) 10-2015-0020108

(51) Int. Cl. H05K 1/02; H05K 1/03; H05K 3/00

(52) U.S. Cl. CPC H05K 1/0271; H05K 3/0047; H05K 1/0306; H05K 2201/09036; H05K 2201/09136; H05K 2201/10204

(57) ABSTRACT

A printed circuit board and a method of manufacturing the same are provided. The printed circuit board includes a core substrate having a cavity formed therein and a dummy chip inserted in the cavity.

### CROSS-REFERENCE TO RELATED APPLICATIONS

This application claims the benefit under 35 USC 119(a) of Korean Patent Application No. 10-2015-0020108, filed on Feb. 10, 2015, in the Korean Intellectual Property Office, the entire disclosure of which is incorporated herein by reference for all purposes.

### BACKGROUND

1. Field

The following description relates to a printed circuit board and a method of manufacturing the same.

2. Description of Related Art

Embedded printed circuit board (PCB) technology for embedding devices that used to be mounted on PCBs has been developed and improved upon to meet the demands for thinner and smaller electronic products that are becoming increasingly integrated. With the improvement of the embedded PCB technology, the number and size of cavities to be processed in the product have been also increased. As more cavities are formed and various devices are embedded within these cavities during the manufacturing process of an embedded product, warpage of the PCB often results as an inevitable consequence of embedding the various devices. Moreover, the bigger the cavity, the degree of warpage tends to be greater. To prevent the warpage of the PCB, materials different from the conventional materials of the PCB, such as glass, ceramic materials and the like, have been inserted in the PCB. Some examples of these PCBs include PCBs having a glass core inserted therein, PCBs embedded with a Cu lump or graphite for heat-dissipation, or embedded active device (EAD) PCBs in which an active device is embedded therein. U.S. Patent Publication No. 2012/0037411 described an example of packaging substrate including a core board and dielectric layer unit to reduce the height of the overall structure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a core substrate having a cavity formed therein, and a dummy chip inserted in the cavity.

The general aspect of the printed circuit board may further include a circuit layer formed on a surface of the core substrate and a surface of the dummy chip.

The cavity may have a tapered shape or an inverse tapered shape.

The dummy chip may have a shape that corresponds to that of the cavity.

The general aspect of the printed circuit board may further include a resin layer filling a space between a sidewall of the cavity and the dummy chip.

The dummy chip may include a material having a greater rigidity than that of the core substrate.

The dummy chip may include glass.

The general aspect of the printed circuit board may further include a build-up layer formed on a surface of the core substrate.

In another general aspect, a method of manufacturing a printed circuit board involves obtaining a dummy chip, obtaining a core substrate having a cavity therein, and inserting the dummy chip into the cavity.

The dummy chip may be obtained by laser drilling a dummy substrate having a greater rigidity than that of the core substrate to have a tapered shape.

The dummy substrate may include a glass substrate.

The core substrate having the cavity therein may be obtained by laser drilling the cavity in the core substrate.

In the obtaining of the core substrate having the cavity therein, the cavity may be formed in a tapered shape or an inverse tapered shape.

The general aspect of the method may further involve, after the inserting of the dummy chip in the cavity, filling a resin into the cavity such that a space between a sidewall of the cavity and the dummy chip is substantially filled by the resin.

The general aspect of the method may further involve, after the filling of the resin, forming a circuit layer on a surface of the core substrate and a surface of the dummy chip.

The general aspect of the method may further involve forming a build-up layer on a surface of the core substrate.

The general aspect of the method may further involve, after the filling of the resin, forming circuit layers on both surfaces of the core substrate and both surfaces of the dummy chip.

Other features and aspects will be apparent from the following detailed description, the drawings, and the claims.

### BRIEF DESCRIPTION OF DRAWINGS

FIG. 1 is a cross-sectional view illustrating an example of a printed circuit board.

FIGS. 2A through 2E are cross-sectional views sequentially illustrating an example of a method of manufacturing a printed circuit board.

FIG. 3 shows widths of A and B of a taper-shaped dummy chip according to an example of the present disclosure.

FIG. 4 is a flowchart illustrating an example of a method of manufacturing a printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

An aspect of the present disclosure provides a printed circuit board that includes a dummy chip that is obtained by processing a glass substrate directly. By embedding the dummy chip in a board, a warpage of the board and a reliability of an embedded PCB may be improved.

Another aspect of the present disclosure provides a method of manufacturing a printed circuit board in which a dummy chip that is obtained by processing a glass substrate directly is embedded in a board. By embedding the dummy chip in the board, a warpage of the board and a reliability of an embedded PCB may be improved.

Hereinafter, certain embodiments of the present disclosure will be described in detail with reference to the accompanying drawings.

### Printed Circuit Board

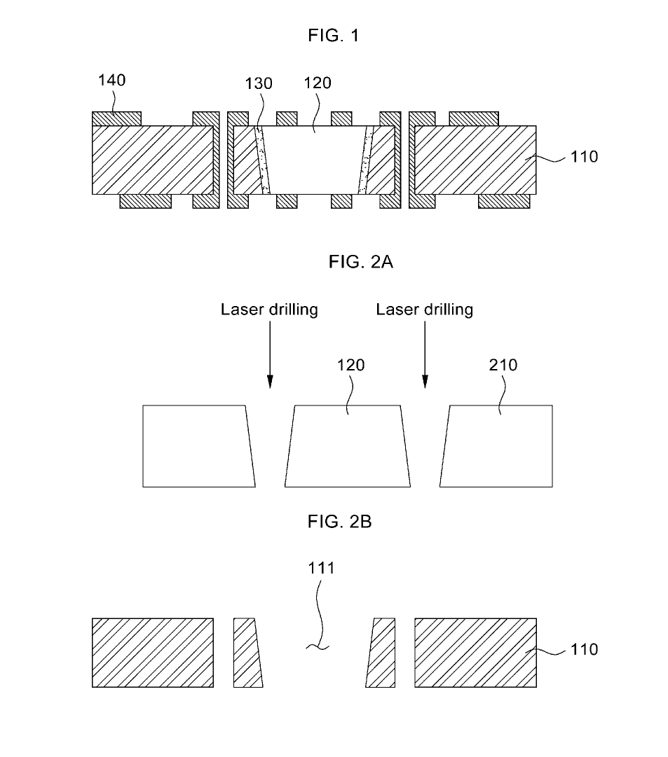

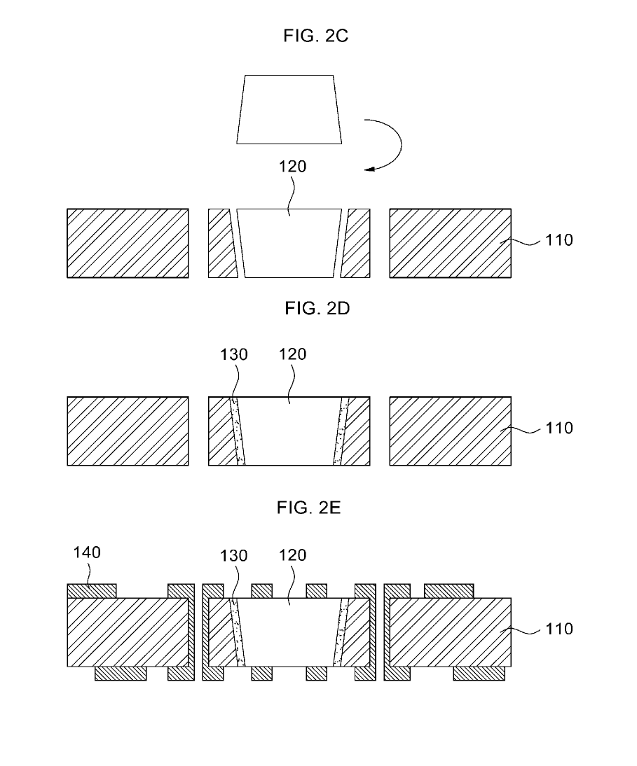

FIG. 1 illustrates a cross-sectional view of an example of a printed circuit board. Referring to FIG. 1, the example of the printed circuit board includes a core substrate 110 having a cavity 111 (see FIG. 2B) formed therein in a tapered shape, a dummy chip 120 processed to have a tapered shape corresponding to the shape and size of the taper-shaped cavity 111 and installed within the cavity 111, a resin layer 130 disposed to fill a space between a sidewall of the cavity 111 and the dummy chip 120 installed in the cavity, and circuit layers 140 formed on an upper surface and a lower surface of the core substrate 110.

The core substrate 110 includes the cavity 111 formed therein. The dummy chip 120 is later installed in the cavity 111. The core substrate 110 also includes a through-hole that penetrated through the core substrate 110 in the vertical direction of the core substrate 110. In this example, the cavity 111 may be laser drilled to have a tapered shape that becomes narrower toward the bottom of the core substrate 110. The cavity 111 may be formed in any size as long as it corresponds to the size of the dummy chip 120. The dummy chip 120 is installed in the cavity 111 in order to prevent a warpage of the board. The core substrate 110 may be made of a resin insulation material. The resin insulation material may be, for example, a thermosetting resin such as epoxy resin, a thermoplastic resin such as polyimide, or a prepreg having a stiffener such as glass fiber or inorganic filler impregnated in the thermosetting or thermoplastic resin.

In this example, the dummy chip 120 is formed by laser drilling a glass substrate 210 (see FIG. 2A). By nature, an upper portion and a lower portion of a laser drilled object are not formed to be identical with each other. In this example, the laser drilled object is formed to have a tapered shape that is wider toward the lower portion. Accordingly, since the cavity 111 of the core substrate 110 is laser drilled, the cavity 111 is formed in a tapered shape. As the dummy chip 120 has upper and lower portion shapes that are inverse of those of the cavity 111, the dummy chip 120 is inversed and inserted into the cavity 111 in an inverse tapered shape. The dummy chip 120 is inserted in the cavity 111 in order to improve the warpage property, rather than building up an additional reinforcing layer on the board. Accordingly, it is possible to form an additional build-up layer later on the core substrate 110 having the dummy chip 120 installed therein.

The resin layer 130 is injected into an inner space of the cavity 111 having the dummy chip 120 installed therein such that the dummy chip 120 is affixed to the cavity 111. In this example, the resin layer 130 may be made of a thermosetting or thermoplastic polymer material, a ceramic, an organic or inorganic composite material, or any resin having glass fiber impregnated therein. According to one example, the resin layer 130 may be made of a polymer resin. The polymer resin may include an epoxy insulation resin, for example, flame retardant 4 (FR-4), bismaleimide triazine (BT) or an Ajinomoto build-up film (ABF). Alternatively, the polymer resin may include a polyimide resin. However, the material for the resin layer 130 may not be limited thereto to these examples.

The circuit layer 140 may be formed using a subtractive process, an additive process, a semi-additive process (SAP), or a modified semi-additive process (MSAP). The subtractive process may involve using an etching resist to selectively remove a metallic material formed in the through-hole of the core substrate 110 and on both surfaces of the core substrate 110 and both surfaces of the dummy chip 120. The additive process may involve using electroless copper plating and electrolytic copper plating.

Therefore, according to the present example, it is possible to minimize the warpage of the board while various devices are inserted into the PCB, and to prevent the warpage that may occur by the embedding of components by minimizing the space that is filled with an insulation material. Thus, it is possible to obtain a sufficient space within a unit based on the cavity size. That is, by directly processing a glass substrate to fabricate the dummy chip and embedding the fabricated dummy chip in the cavity of the core substrate, it is possible to prevent the warpage and increase the reliability of the PCB.

### Method of Manufacturing Printed Circuit Board

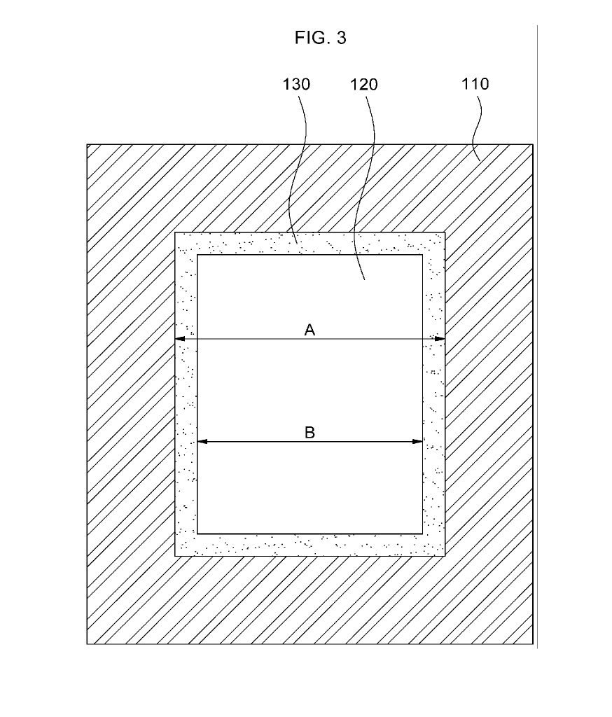

FIGS. 2A through 2E illustrate processes used in an example of a method of manufacturing a printed circuit board by illustrating cross-sectional views of the printed circuit board during a manufacturing process. FIG. 3 shows widths of A and B of a taper-shaped dummy chip according to an example of a printed circuit board.

Firstly, referring to FIG. 2A, a glass substrate 210 is processed in a tapered shape to form a dummy chip 120. The dummy chip 120 may be formed of a material having a greater rigidity that that of a core substrate, such as, for example, a glass substrate. In this example, the glass substrate 210 may be formed by laser drilling in a tapered shape that becomes narrower toward the bottom of the dummy chip 120. By nature, an upper portion and a lower portion of a laser drilled object are not formed so as to be identical with each other. In this example, the laser drilled object is formed to have a tapered shape that is wider toward the lower portion of the dummy chip 120. The dummy chip 120 may be formed in any size as long as it corresponds to a size of the cavity in which the dummy chip 120 is to be installed.

Referring to FIG. 2B, a cavity 111 of a core substrate 110 has a tapered shape according to the size of the dummy chip 120, and a through-hole penetrates the core substrate 110 in a thickness direction thereof. In this example, the cavity 111 may be laser drilled to have a tapered shape that becomes narrower toward the bottom of the core substrate 110. The cavity 111 may be formed to have any size, but a front portion and a rear portion of the core substrate 110 may be obtained by adjusting the tapered size of the cavity 111 and the tapered size of the dummy chip 120. The core substrate 110 may be made of a resin insulation material. The resin insulation material may be, for example, a thermosetting resin such as epoxy resin, a thermoplastic resin such as polyimide, or a prepreg having a stiffener such as glass fiber or inorganic filler impregnated in the thermosetting or thermoplastic resin.

Referring to FIG. 2C, the dummy chip 120 is installed in the cavity 111 of the core substrate 110. In this example, as the dummy chip 120 has upper and lower portion shapes that are inverse of those of the cavity 111 of the core substrate 110, the dummy chip 120 is inversed and inserted into the cavity 111 in an inverse trapezoid shape.

Referring to FIG. 3, the dummy chip 120 is formed in such a manner that a width A of an upper portion thereof is greater than a width B of a lower portion thereof. The dummy chip 120 is inserted in the cavity 111 of the core substrate 110, instead of building up an additional reinforcing layer on the PCB, in order to improve the warpage property of the core substrate 110.

Referring to FIG. 2D, a resin is filled into a space of the cavity 111 in which the dummy chip 120 is installed. In this example, the resin layer 130 is injected into the space between a side wall of the cavity 111 and the dummy chip 120 installed therein such that the dummy chip 120 is affixed to the cavity 111. The resin layer 130 may be made of a thermosetting or thermoplastic polymer material, a ceramic, an organic or inorganic composite material, or any resin having glass fiber impregnated therein. According to one example, the resin layer 130 is made of a polymer resin, and the polymer resin includes an epoxy insulation resin, such as flame retardant 4 (FR-4), bismaleimide triazine (BT) or an Ajinomoto build-up film (ABF). Alternatively, the polymer resin may include a polyimide resin; however, the material for the resin layer is not limited thereto.

Referring to FIG. 2E, after filling in the space with the resin, a circuit layer 140 is formed on both surfaces of the core substrate 110. In this example, the circuit layer 140 is formed simultaneously on both surfaces of the dummy chip 120.

In this example, the circuit layer 140 may be formed using a subtractive process, an additive process, a semi-additive process (SAP), or a modified semi-additive process (MSAP). The subtractive process may involve using an etching resist to selectively remove a metallic material formed in the through-hole of the core substrate 110 and on the both surfaces of the core substrate 110 and the both surfaces of the dummy chip 120. The additive process may involve using electroless copper plating and electrolytic copper plating.

Meanwhile, in various other examples of the present disclosure, the core substrate 110 having the circuit layer 140 formed thereon may further have another cavity formed therein and a build-up layer formed thereon for installation of an electronic component.

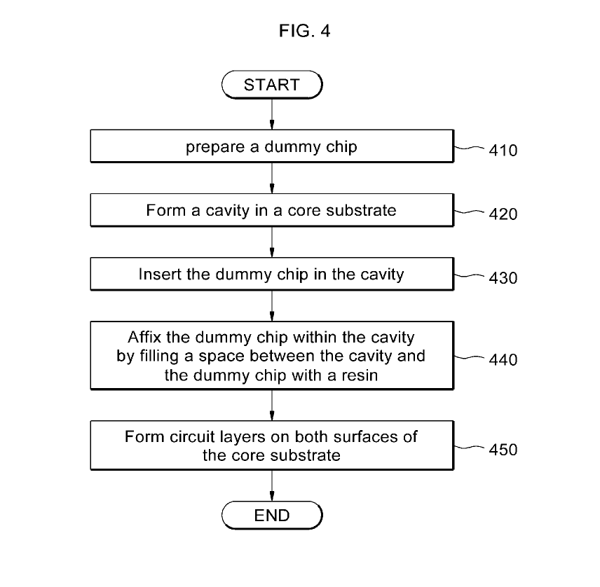

FIG. 4 illustrates another example of a method of manufacturing a printed circuit board. Descriptions that are redundant with respect to examples illustrated in FIGS. 1-3 will be omitted.

Referring to FIG. 1, the method of manufacturing the printed circuit board involves the process of preparing a dummy chip 120 from a glass substrate 210 (410), forming a cavity 111 in a core substrate 110 (420), inserting the dummy chip 120 in the cavity 111 (430), affixing the dummy chip 120 within the cavity 111 by filling a space between the cavity 111 and the dummy chip 120 with a resin insulation material to form the resin layer 130 (440) and forming circuit layers 140 on both surfaces of the core substrate 110 (450).

The preparing of the dummy chip 120 (410) and the forming of the cavity 111 in the core substrate 110 may occur simultaneously or in reverse order. The circuit layer 140 may be formed on both surfaces or on one surface of the core substrate 110. The resin layer 130 may be injected into an inner space of the cavity 111 having the dummy chip 120 installed therein such that the dummy chip 120 is affixed to the cavity 111. According to one example, the resin layer 130 substantially fills the space between the dummy chip 120 and a sidewall of the cavity 111.

Therefore, according to the examples above, it is possible to minimize the warpage of the PCB while various devices are inserted in the PCB, to prevent the warpage that occurs due to the embedding of various devices by minimizing the space to be filled with an insulation material in the PCB, to use an insulation layer with a smaller amount of resin being filled and with a higher coefficient of thermal expansion, and to obtain a sufficient space within a unit based on the cavity size.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a core substrate having a cavity formed therein; and
a dummy chip inserted in the cavity.

2. The printed circuit board as set forth in claim 1, further comprising a circuit layer formed on a surface of the core substrate and a surface of the dummy chip.

3. The printed circuit board as set forth in claim 1, wherein the cavity has a tapered shape or an inverse tapered shape.

4. The printed circuit board as set forth in claim 1, wherein the dummy chip has a shape corresponding to that of the cavity.

5. The printed circuit board as set forth in claim 1, further comprising a resin layer filling a space between a sidewall of the cavity and the dummy chip.

6. The printed circuit board as set forth in claim 1, wherein the dummy chip comprises a material having a greater rigidity than that of the core substrate.

7. The printed circuit board as set forth in claim 6, wherein the dummy chip comprises glass.

8. The printed circuit board as set forth in claim 1, further comprising a build-up layer formed on a surface of the core substrate.

9. A method of manufacturing a printed circuit board, comprising:
obtaining a dummy chip;
obtaining a core substrate having a cavity therein; and
inserting the dummy chip into the cavity.

10. The method as set forth in claim 9, wherein the dummy chip is obtained by laser drilling a dummy substrate having a greater rigidity than that of the core substrate to have a tapered shape.

11. The method as set forth in claim 10, wherein the dummy substrate comprises a glass substrate.

12. The method as set forth in claim 9, wherein the core substrate having the cavity therein is obtained by laser drilling the cavity in the core substrate.

13. The method as set forth in claim 12, wherein, in the obtaining of the core substrate having the cavity therein, the cavity is formed in a tapered shape or an inverse tapered shape.

14. The method as set forth in claim 9, further comprising, after the inserting of the dummy chip in the cavity, filling a resin into the cavity such that a space between a sidewall of the cavity and the dummy chip is substantially filled by the resin.

15. The method as set forth in claim 14, further comprising, after the filling of the resin, forming a circuit layer on a surface of the core substrate and a surface of the dummy chip.

16. The method as set forth in claim 9, further comprising forming a build-up layer on a surface of the core substrate.

17. The method as set forth in claim 14, further comprising, after the filling of the resin, forming circuit layers on both surfaces of the core substrate and both surfaces of the dummy chip.
